(19) United States
(12) Patent Application Publication
(10) Pub. No.: US 2005/0221612 A1
(43) Pub. Date: Oct. 6, 2005

(54) A LOW THERMAL BUDGET (MOL) LINER, A SEMICONDUCTOR DEVICE COMPRISING SAID LINER AND METHOD OF FORMING SAID SEMICONDUCTOR DEVICE

(75) Inventors: Laura Brown, Pleasant Valley, NY (US); Fen F. Jamin, Wappingers Falls, NY (US); Kin-Sang Lam, Hopewell Junction, NY (US); Ying Li, Newburgh, NY (US); Yun Y. Wang, Poughquag, NY (US); Horatio S. Wildman, Wappingers Falls, NY (US); Kwong H. Wong, Wappingers Falls, NY (US)

Correspondence Address: SCULLY SCOTT MURPHY & PRESSER, PC, 400 GARDEN CITY PLAZA, SUITE 300, GARDEN CITY, NY, 11530, US

(73) Assignees: INTERNATIONAL BUSINESS MACHINES CORPORATION, Armonk, NY (US); ADVANCED MICRO DEVICES, INC., Sunnyvale, CA (US)

(21) Appl. No.: 10/708,978

(22) Filed: Apr. 5, 2004

(51) Int. Cl. H01L 21/425

(52) U.S. Cl. 438/643

(57) ABSTRACT

The present invention is directed to a low thermal budget MOL liner to be used in the fabrication of a semiconductor device. The low thermal budget MOL liner of the present invention, which is formed by treating a titanium-deposited layer with an in-situ plasma nitridization step, results in a significantly improved high performance device as the need for the higher thermal annealing process presently used in the making of such devices can be avoided. The present invention is further directed to a method of making the resulting semiconductor device, as well as the semi-conductor device itself.

### BACKGROUND OF INVENTION

The present invention generally relates to the semiconductor processing of high performance devices, particularly devices employing silicide contacts. More specifically, the present invention is directed to a low thermal budget MOL (middle of the line) liner that protects the silicide and results in an improved general usability of the semiconductor device. The invention is further related to the method of forming the low thermal budget (MOL) liner in the fabrication of a semiconductor device, as well as the semiconductor device itself.

In the formation of integrated circuits, thin films containing metal or metalloid elements are deposited upon the surface of a semiconductor substrate or wafer, and then annealed using a silicide annealing forming Ohmic contacts. These films provide conductive and Ohmic contacts in the circuits and between the various devices of the integrated circuit. An interconnect dielectric is then formed atop the substrate and via or contact openings that expose the Ohmic contacts are formed. A thin film of a desired metal may be applied, for example, to the exposed surface of the Ohmic contact. The film, which passes through the insulative layers of the interconnect structure, acts as a plug of conductive material, making interconnections across the insulating layers. Well-known processes for depositing thin metal films include chemical vapor deposition (CVD) and physical vapor deposition (PVD), with the latter also referred to as sputtering.

As the dimensions of the integrated circuit components continue their evolution to minute feature sizes (e.g., sub-micron dimensions), the materials used to fabricate such components are crucial as they contribute to the electrical performance of the device. For example, low resistivity metal interconnects, such as aluminum and copper, provide conductive paths between the components of an integrated circuit. Typically, the metal interconnects are electrically isolated from each other by an insulating material.

Additionally, a liner material is often employed to separate the metal interconnects from the insulating material. The liner material acts as a barrier layer, inhibiting the diffusion of the metal into the insulating material. Diffusion of the metal into the insulating material is undesirable as such an occurrence can significantly affect the electrical performance of the integrated circuit, or render it inoperative altogether. A combination of titanium (Ti) and/or titanium nitride (TiN) is generally used for the liner material.

Accordingly, new liner materials and/or the process technologies associated therewith are being required to ensure high device performance. These liners not only must possess mechanical and structural integrity, conform well within the aggressive features of the device concerned, be mechanically, electrically and thermally compatible with the neighboring conductor and dielectric material systems of the device and possess high conductivity to minimize overall contact resistance, they must also meet these requirements at increasingly reduced thicknesses in order to maximize the space available in the continuously decreasing device dimensions.

Silicides, which are compounds formed from a metal and silicon, are commonly used for contacts in semiconductor devices. Silicide contacts provide several advantages over contacts formed from other materials, such as aluminum or polysilicon. Silicide contacts are thermally stable, have lower resistivity than polysilicon, and provide for good Ohmic contacts. In addition, silicide contacts are more reliable because the silicidation reaction eliminates many defects at the interface between the contact and the device feature.

In the semiconductor processing of memory and logic devices employing silicide contacts, such as a field effect transistor (FET), tungsten (W) is the standard metal contact between the silicide and the back end of the line (BEOL) insulators. Due to the aggressive nature of tungsten fill chemistry, a liner, e.g. MOL liner, must be used to protect the silicide. The state-of-the-art liner process includes a pre-clean of the substrate, such as wet sputtering or Argon sputtering, the deposit of a layer of titanium (Ti) followed by a chemical vapor deposition of a titanium nitride (TiN) layer, further followed by a thermal annealing process done in forming gas at a temperature of 550° C.

The purpose of the Ti is to act as an oxide getter and to form titanium silicide. Without the Ti, the contact resistance of the Si would be very high. On the other hand, excess Ti is also undesirable in that it will form TiF₄ during the subsequent WF₆ (i.e. tungsten fill) process. In order to avoid this, an extra layer of TiN is deposited, usually by CVD, and the entire liner is subjected to a forming gas anneal at temperatures of about 550° C. for a period of ½ hour or longer. In this thermal annealing process, any free Ti is converted into TiN.

As noted above, the feature sizes of semiconductor devices are getting smaller and smaller. The liner process described above is not acceptable because the CVD TiN layer has a relatively high electrical resistivity. Furthermore, the dopant level will be disturbed by the relatively high thermal anneal process. Still even further, some silicide such as NiSi will agglomerate and the device performance will suffer as a result from the high temperature processing.

In view of the drawbacks caused predominantly by the high thermal budget annealing process, new and improved semiconductor devices employing silicide contacts are demanded by today's standards.

### SUMMARY OF INVENTION

The present invention provides a low thermal budget MOL liner comprising a titanium-deposited layer that has been subjected to an in-situ gas plasma nitridization process.

Further, the present invention provides a semiconductor device having silicide contacts and comprising said low thermal budget MOL liner.

Still further, the present invention provides a method for making said semiconductor device. More specifically, and in broad terms, the method of the present invention comprises:

depositing a titanium layer on an interconnect structure having one or more contact openings which expose one or more silicide regions;

subjecting the deposited titanium layer to an in-situ plasma nitridization wherein any free titanium is converted into titanium nitride;

depositing at least one layer of titanium nitride on the in-situ plasma-treated titanium layer; and

filling the contact openings with tungsten.

Optionally, the interconnect structure can be subjected to a surface cleaning prior to depositing the titanium layer on the interconnect structure.

### BRIEF DESCRIPTION OF DRAWINGS

FIG. 1 is a pictorial representation (through a cross sectional view) of an initial interconnect structure that can be employed in the present invention, said interconnect structure including a silicon substrate and silicide regions formed above the active regions thereof (e.g. the source, drain and gate regions).

FIG. 2 is a pictorial representation (through a cross sectional view) of the initial structure of FIG. 1 after having a titanium layer deposited thereon.

FIG. 3 is pictorial representation (through a cross sectional view) of the final structure in accordance with the present invention.

FIG. 4 is the Auger profile of a blanket layer of Ti on SiO₂ that was treated in an NH₃ plasma evidencing the amount of TiN formation.

### DETAILED DESCRIPTION

The present invention will now be described in greater detail by referring to the drawings that accompany the present application. It should be noted that the drawings of the present application are not drawn to scale.

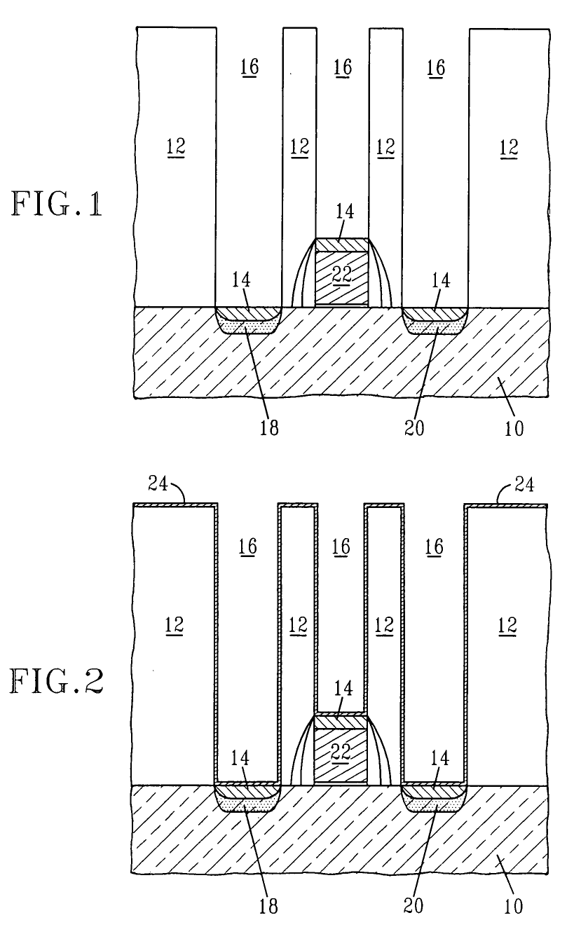

Reference is first made to the initial interconnect structure that is shown in FIG. 1. The interconnect structure can be made by using any BEOL process well known in the art, said process including the deposition of a dielectric layer onto a silicon substrate containing one or more devices and one or more silicide regions, and the formation of vias and contact openings using state-of-the-art processes such as lithography and etching.

More specifically, the initial interconnect structure shown in FIG. 1 comprises a silicon substrate 10, a dielectric layer 12 deposited thereon, one or more contact openings 16 formed in said dielectric layer 12 which expose one or more silicide regions 14. Said silicide regions 14 or silicide contacts are formed above the active regions on the substrate, i.e. the source 18, the drain 20 and the gate 22. The silicide contacts are formed using any conventional silicide process and the gate is formed using any conventional CMOS process.

The silicon substrate 10 is any conventional crystalline silicon substrate. For example, the silicon-containing substrate 10 may include any semiconductor material that includes silicon. Examples of Si-containing substrates 10 that can be employed in the present invention include, but are not limited to: Si, SiGe, SiGeC, SiC, silicon-on-insulators, or SiGe-on-insulators. Alternatively, the Si-containing substrate 10 may include a stack structure wherein a Si layer such as epi-Si or amorphous Si is formed atop a semiconductor substrate.

The dielectric layer 12 may also be made of any standard dielectric materials known in the art and include both organic and inorganic materials having a dielectric constant that is typically less than silicon dioxide.

The silicide regions or contacts 14 can be any type of silicide, such as cobalt, nickel, titanium, tungsten, platinum and molybdenum. Of these, titanium, cobalt and nickel are preferred, with cobalt and nickel being most preferred.

The first step in the method of the present invention is to surface clean the interconnect structure. It is particularly important to clean the surface of an interconnect structure upon which subsequently will be deposited a thin metallic film. Most metals will readily adhere to a clean insulating surface. If, however, the surface is contaminated with a foreign substance, the adhesion of the film will be degraded and there will exist the tendency for the metal film to crack and peel. The pre-cleaning step to be used in the method of the present invention can be accomplished by using any conventional pre-cleaning process known to those skilled in the art, including, but not limited to, wet cleaning, argon sputtering or plasma chemical cleaning. Of those mentioned, the wet or argon sputtering clean are preferred.

The second step of the method in accordance with the present invention is the depositing of a Ti layer over the interconnect structure. This step is illustrated in FIG. 2. Any conventional method can be used to deposit the Ti layer 24, however, sputtering or PVD is the preferred method. The Ti layer 24 is generally deposited with a thickness range of between about 25 Å to about 250 Å.

The third step in the method of the present invention involves an in-situ plasma nitridization process in which any free Ti is converted into TiN. This is accomplished in a hydrogen, nitrogen gas environment and can be represented by the following chemical equations:
Ti+oxide→Ti(O), TiO (i)
Ti (free)+N₂→TiN (ii)

Equation (i) above illustrates the fact that the Ti acts as an oxide getter by reacting with the surface oxide to form a solid solution of Ti(O), as well as free TiO. More importantly, during the in-situ plasma nitridization step represented by equation (ii), all free titanium is converted to inert titanium nitride. This accomplishes several benefits. First of all, the conversion of the free titanium to titanium nitride leads to low contact resistance. It also allows for a thinner CVD TiN to be employed in the next step. CVD TiN has a much higher contact resistance than PVD TiN, but is needed for all small devices because it has a better step coverage than PVD Ti. Additionally, no free Ti means no volcanic eruption due to TiF₄ formation in the subsequent tungsten fill step.

The in-situ plasma conversion step is typically performed at a temperature between room temperature and upwards to about 410° C. for a period of time between about 5 to about 60 seconds. Preferably, the in-situ plasma conversion of titanium into titanium nitride is accomplished at a temperature of between about 325° C. to about 400° C., most preferably at a temperature of about 350° C., and for a period of time between about 5 to 45 seconds, most preferably for a period of about 25 seconds. The step is typically performed in a CVD TiN chamber with nitrogen and hydrogen gas with pressures between about 100 mTorr to about 5 Torr.

The next step in the method of the present invention is the depositing of at least one or more layers of CVD TiN, said layer or layers each having a thickness in the range of between about 15 Å to about 100 Å. This depositing step may be performed by any conventional CVD process. In said CVD process, a TiN layer is formed by thermally decomposing a titanium-containing precursor and a nitrogen-containing precursor. Suitable titanium-containing precursors include tetrakisdimethylamino titanium (TDMAT), tetrakisdiethylamino titanium (TDEAT), and titanium tetrachloride (TiCl₄). Suitable gaseous sources or precursors of nitrogen include ammonia gas (NH₃) and the nitrogen radical activated by plasma. The CVD process is generally performed at a temperature between about 350° C. to about 550° C.

The final step in the method according to the present invention is a tungsten-filling step. One such conventional way of bulk tungsten filling is by forming the tungsten by hydrogen or silane reduction of tungsten hexaflouride (WF₆) in a CVD process.

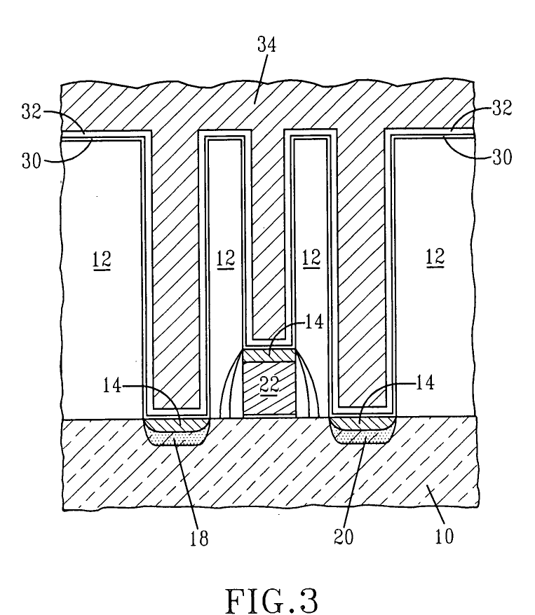

FIG. 3 illustrates the final interconnect structure made in accordance with the method of the present invention and shows the low thermal budget MOL liner 30, a CVD TiN layer 32 and the CVD tungsten fill 34.

In the prior art method, the CVD TiN step was followed by a thermal annealing process. Such a process involved temperatures of 400° C. and higher, more typically around the 650° C. range, for a period of at least 30 minutes. By employing the in-situ plasma nitridization step in the method of the present invention, the thermal annealing process can be avoided altogether. Thus, the thermal annealing process just described has been effectively replaced by a process preferably performed at a temperature of about 350° C. to 385° C. and for a period of about 5 to 35 seconds. Obviously, this is extremely important as the in-situ plasma nitridization step of the present method possesses a significantly much lower thermal budget. This translates into a greater preservation of the implantation profile of the resulting high performance device and, more importantly, reduces the nickel defects in the final device.

The prior art, as mentioned above, uses either a long thermal anneal process which is totally unacceptable for high performance devices using nickel silicides, or a TiN layer as a glue/interconnect layer which is not robust enough in interconnect structures having small vias/high aspect ratio structure to withstand the WF₆ attack during the subsequent tungsten bulk fill process.

The thin, low thermal budget and robust liner in accordance with the present invention avoids any overhang over the top of the high aspect via structures and, consequently enables a better tungsten bulk fill. That is, with the presence of the low thermal budget liner of the present invention, less voids and no trapping of CMP slurries are encountered in subsequent processing steps.

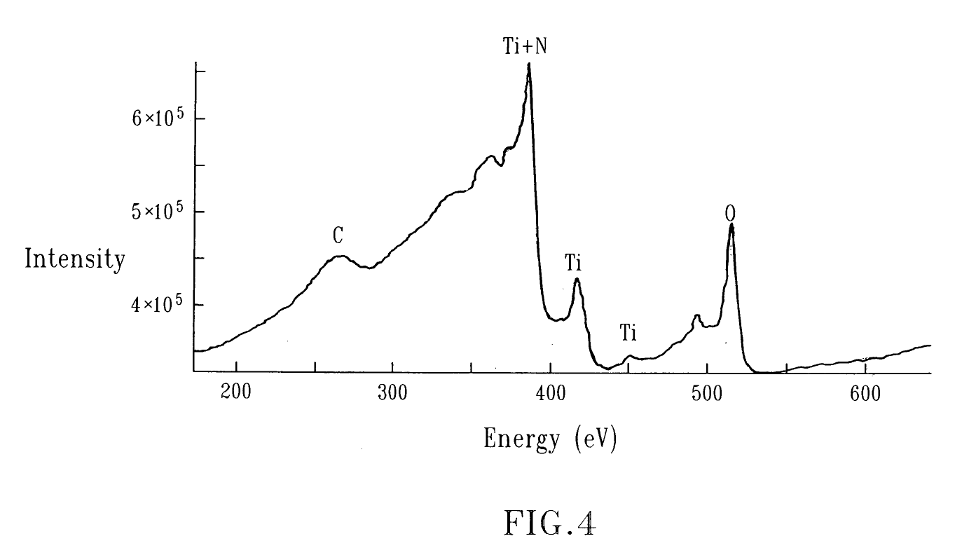

FIG. 4 is an Auger profile of a blanket layer of Ti on SiO₂ that was treated in an NH₃ plasma evidencing the amount of TiN formation. Auger electron spectroscopy (AES) is a method used to identify elemental compositions of surfaces by measuring the energies of Auger electrons. Each element in a sample being profiled will give rise to its own unique characteristic spectrum of peaks at various kinetic energies. FIG. 4 shows that the in-situ forming gas plasma step used in the method of the present invention can effectively convert all free titanium to unreactive and low resistivity PVD TiN. Thus, this evidences the ability of the process of the present invention to avoid the necessity of employing the thermal annealing process of the prior art. As already explained, the differences between the temperatures and length of time that the temperatures are applied in the prior art thermal annealing step as compared to the in-situ plasma nitridization step of the present invention are significantly great and lead to an improved high performance semiconductor device.

While this invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

1. A method of making an interconnect structure comprising the steps of:
depositing a titanium layer on an interconnect structure having one or more contact openings which expose one or more suicide regions;
subjecting said deposited titanium layer to an in-situ plasma nitridization process;
depositing at least one layer of titanium nitride on said in-situ plasma-treated titanium layer; and
filling said contact openings with tungsten.

2. The method of claim 1 wherein the silicide of said silicide regions is comprised of silicon and a metal selected from the group consisting of cobalt, nickel, titanium, tungsten, platinum and molybdenum.

3. The method of claim 2 wherein said silicide is comprised of a nickel silicide.

4. The method of claim 2 wherein said silicide is comprised of a cobalt silicide.

5. The method of claim 2 wherein said silicide is comprised of a titanium silicide.

6. The method of claim 1 wherein prior to depositing said titanium layer on said interconnect structure, said interconnect structure undergoes surface cleaning.

7. The method of claim 1 wherein said titanium layer is deposited on said silicon substrate by a physical vapor deposition process.

8. The method of claim 1 wherein said titanium layer has a thickness of between about 25 Å to about 250 Å.

9. The method of claim 1 wherein said in-situ plasma nitridization process comprises converting all free titanium into titanium nitride in a hydrogen and nitrogen gas environment.

10. The method of claim 1 wherein said in-situ plasma nitridization process is performed at a temperature from between about room temperature to about 410° C.

11. The method of claim 11 wherein said in-situ plasma nitridization process is performed at a temperature from between about 325° C. to about 400° C.

12. The method of claim 12 wherein said in-situ plasma nitridization process is performed at a temperature of about 350° C.

13. The method of claim 1 wherein said in-situ plasma nitridization process is performed for a period of from between about 5 to about 60 seconds.

14. The method of claim 13 wherein said in-situ plasma nitridization process is performed for a period of from between about 5 to about 45 seconds.

15. The method of claim 14 wherein said in-situ plasma nitridization process is performed for a period of about 25 seconds.

16. The method of claim 1 wherein said at least one titanium nitride layer is deposited on said in-situ plasma-treated titanium layer by a chemical vapor deposition process.

17. The method of claim 16 wherein said CVD process involves using a titanium-containing precursor selected from the group consisting of TDMAT, TDEAT and titanium tetrachloride.

18. The method of claim 16 wherein said CVD process involves using a nitrogen-containing precursor of ammonia.

19. The method of claim 1 wherein each of said at least one titanium nitride layer has a thickness of between about 15 Å to about 100 Å.

20. The method of claim 1 wherein at least two layers of titanium nitride are deposited on said in-situ plasma-treated titanium layer.

21. A low thermal budget MOL liner comprising a titanium-deposited layer that has been subjected to an in-situ gas plasma nitridization process.

22. The low thermal budget MOL liner of claim 21 wherein said liner has a thickness of between about 25 Å to about 250 Å.

23. A semiconductor device having a silicide contact, comprising
an interconnect structure having one or more contact openings which expose one or more silicide regions;
a low thermal budget MOL liner formed above said silicide contact, said liner comprising a titanium-deposited layer that has been subjected to an in-situ gas plasma nitridization process; and
one or more titanium nitride layers deposited on said low thermal budget MOL liner.

24. The semiconductor device of claim 23 wherein said silicide contact is comprised of silicon and a metal selected from the group consisting of cobalt, nickel, titanium, tungsten, platinum and molybdenum.

25. The semiconductor device of claim 24 wherein said silicide contact is comprised of a nickel silicide.

26. The semiconductor device of claim 24 wherein said silicide is comprised of a cobalt silicide.

27. The semiconductor device of claim 23 wherein said titanium-deposited layer has a thickness of between about 25 Å to about 250 Å.

28. The semiconductor device of claim 23 wherein each of said one or more titanium nitride layers has a thickness of between about 15 Å to about 100 Å.

29. The semiconductor device of claim 23 wherein said semiconductor device is subjected to a bulk tungsten filling step.

30. The semiconductor device of claim 29 wherein said bulk tungsten filling step is performed by a CVD process.
